(19) United States
(12) Patent Application Publication
(10) Pub. No.: US 2026/0282516 A1
(43) Pub. Date: Sep. 17, 2026

(54) SEMICONDUCTOR DEVICE

(71) Applicants: KABUSHIKI KAISHA TOSHIBA, Kawasaki-shi (JP); TOSHIBA ELECTRONIC DEVICES & STORAGE CORPORATION, Kawasaki-shi (JP)

(72) Inventors: Hiroki SAKATA, Kawasaki Kanagawa (JP); Tatsuya NISHIWAKI, Yokohama Kanagawa (JP); Kentaro ICHINOSEKI, Higashimurayama Tokyo (JP)

(73) Assignees: KABUSHIKI KAISHA TOSHIBA, Kawasaki-shi (JP); TOSHIBA ELECTRONIC DEVICES & STORAGE CORPORATION, Kawasaki-shi (JP)

(21) Appl. No.: 19/373,931

(22) Filed: Oct. 30, 2025

(30) Foreign Application Priority Data
Mar. 17, 2025 (JP) 2025-042046

(51) Int. Cl. H10D 84/00; H10D 84/01

(52) U.S. Cl. CPC H10D 84/146; H10D 84/0109

(57) ABSTRACT

A semiconductor device of an embodiment has a semiconductor member, a source electrode, a drain electrode, a gate electrode, and an insulating layer. The semiconductor member includes a first semiconductor region of a first conductivity type, and a second semiconductor region of a first conductivity type. The first semiconductor region has an ohmic junction portion. The second semiconductor region has a Schottky junction portion, and a second partial region. The second partial region is located between the gate electrode and the source electrode in the second direction. The insulating layer has a bottom face insulating portion, and a sidewall insulating portion. An upper end portion of the sidewall insulating portion is located on the second side of the ohmic junction portion and the Schottky junction portion and on the first side of the second partial region.

### CROSS-REFERENCE TO RELATED APPLICATION

This application is based upon and claims the benefit of priority from Japanese Patent Application No. 2025-042046, filed on Mar. 17, 2025; the entire contents of which are incorporated herein by reference.

### FIELD

Embodiments described herein relate generally to a semiconductor device.

### BACKGROUND

There are semiconductor devices such as metal oxide semiconductor field effect transistors (MOSFETs) that have a Schottky barrier diode within the device. In this type of structure, there is a problem that if an electric field at a Schottky junction portion is high, leakage current becomes large.

### BRIEF DESCRIPTION OF THE DRAWINGS

FIG. 1 is a cross-sectional schematic view of a semiconductor device of an embodiment.

FIG. 2 is a cross-sectional schematic view showing a process of forming a groove for a gate electrode and an internal structure of the groove for a gate electrode in a semiconductor member, in a method of manufacturing the semiconductor device of the embodiment.

FIG. 3 is a cross-sectional schematic view showing a process of causing a first insulating layer to protrude from an upper surface of the semiconductor member, in the method of manufacturing the semiconductor device of the embodiment.

FIG. 4 is a cross-sectional schematic view showing a process of forming a sidewall on the upper surface of the semiconductor member, in the method of manufacturing the semiconductor device of the embodiment.

FIG. 5 is a cross-sectional schematic view showing a process of forming a preliminary concave portion on the upper surface of the semiconductor member, in the method of manufacturing the semiconductor device of the embodiment.

FIG. 6 is a cross-sectional schematic view showing a process of ion-injecting n type impurities to the semiconductor member, in the method of manufacturing the semiconductor device of the embodiment.

FIG. 7 is a cross-sectional schematic view showing a process of forming a groove for a source electrode in the semiconductor member, in the method of manufacturing the semiconductor device of the embodiment.

FIG. 8 is a cross-sectional schematic view showing a process of removing a sidewall and an insulating film, in the method of manufacturing the semiconductor device of the embodiment.

FIG. 9 is a cross-sectional schematic view showing a process of forming a second insulating layer on a surface of the semiconductor member, in the method of manufacturing the semiconductor device of the embodiment.

FIG. 10 is a cross-sectional schematic view showing a process of forming a contact portion in the groove for a source electrode, in the method of manufacturing the semiconductor device of the embodiment.

FIG. 11 is a cross-sectional schematic view showing a process of partially removing the second insulating layer, in the method of manufacturing the semiconductor device of the embodiment.

### DETAILED DESCRIPTION

A semiconductor device of an embodiment has a semiconductor member, a source electrode, a drain electrode, a gate electrode, and an insulating layer. The semiconductor member is provided with a first concave portion and a second concave portion arranged in a second direction crossing a first direction. The first concave portion and the second concave portion are recessed from a surface in the first direction on a first side to a second side opposite to the first side. The source electrode is located on the first side of the semiconductor member. At least a part of the source electrode is located in the second concave portion. The drain electrode is located on the second side of the semiconductor member. At least a part of the gate electrode is located in the first concave portion. The insulating layer is located between an inner side surface of the second concave portion and the source electrode. The semiconductor member includes a first semiconductor region of a first conductivity type, and a second semiconductor region of a first conductivity type. The second semiconductor region is located on the second side of the first semiconductor region. The second semiconductor region has a carrier concentration lower than that in the first semiconductor region. The first semiconductor region has an ohmic junction portion. The ohmic junction portion forms an ohmic junction with the source electrode. The second semiconductor region has a Schottky junction portion, and a second partial region. The Schottky junction portion forms a Schottky junction with the source electrode. The second partial region is located between the gate electrode and the source electrode in the second direction. The insulating layer has a bottom face insulating portion, and a sidewall insulating portion. The bottom face insulating portion covers a bottom face of the second concave portion. The sidewall insulating portion extends from the bottom face insulating portion to the first side and covers a part of the sidewall of the second concave portion. An upper end portion of the sidewall insulating portion is located on the second side of the ohmic junction portion and the Schottky junction portion and on the first side of the second partial region.

Hereinafter, the semiconductor device of the embodiment will be described with reference to the accompanying drawings.

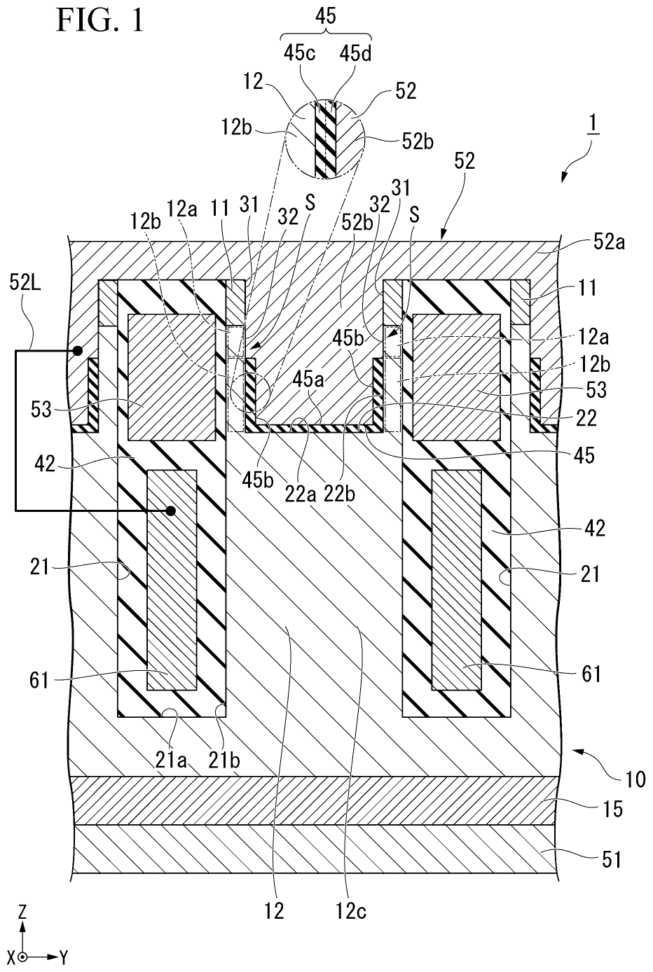

FIG. 1 is a cross-sectional schematic view of a semiconductor device 1 of an embodiment.

The drawings show an X axis, a Y axis, and a Z axis as appropriate. The X axis, the Y axis, and the Z axis are perpendicular to each other.

In this specification, a term “direction” is a concept that encompasses two directions (one side and the other side) that face opposite each other. In the following embodiment, a direction parallel to the Z axis corresponds to “a first direction,” a direction parallel to the X axis corresponds to “a second direction” and a direction parallel to the Y axis corresponds to “a third direction.” Accordingly, a first direction Z, a second direction X, and a third direction Y are three directions crossing each other. In the specification, a side (+Z) in the first direction Z facing an arrow of the Z axis is referred to as an upper side or a first side, and a side (−Z) in the first direction Z opposite to an arrow of the Z axis is referred to as a lower side or a second side. Further, in this specification, the concepts of “upper” and “lower” do not necessarily indicate a relationship with the direction of gravity.

In the following description, notations such as n, n⁺ and n⁻ represent a relative level in impurity concentration in each conductivity type. That is, n⁺ indicates that an n type impurity concentration is relatively higher than that of n, and n⁻ indicates that the n type impurity concentration is relatively lower than that of n.

In the specification, a carrier concentration of the semiconductor region can be measured using, for example, a capacitance-voltage characteristic measurement. In addition, the carrier concentration of the semiconductor region may be calculated from an impurity concentration measured using, for example, secondary ion mass spectrometry (SIMS). A relative magnitude relationship between the carrier concentrations of the two semiconductor regions can be determined using, for example, scanning capacitance microscopy (SCM). In addition, a distribution and absolute values of the carrier concentrations can be measured using, for example, spreading resistance analysis (SRA).

As shown in FIG. 1, the semiconductor device 1 according to the embodiment includes a semiconductor member 10, a drain electrode 51, a source electrode 52, a gate electrode 53, a field plate (conductive member) 61, a first insulating layer 42, and a second insulating layer 45. In the specification, a thickness direction of the semiconductor device 1 is the first direction Z.

The semiconductor device 1 of the embodiment is a trench type Metal-Oxide-Semiconductor Field-Effect Transistor (MOSFET). In addition, the semiconductor device 1 of the embodiment is a Schottky contact-type transistor. The semiconductor device 1 can control a second partial region 12b of the semiconductor member 10 using a potential of the gate electrode 53. That is, the semiconductor device 1 can control current flowing between the drain electrode 51 and the source electrode 52 using the potential of the gate electrode 53.

The semiconductor member 10 includes at least one selected from the group consisting of, for example, silicon (Si), nitride semiconductor (for example, GaN or the like), silicon carbide (SiC), and oxide semiconductor (for example, GaO).

The semiconductor member 10 is in the form of a substrate with the first direction Z as its thickness direction. The drain electrode 51 is located below the semiconductor member 10. In addition, the source electrode 52 is located above the semiconductor member 10. That is, the semiconductor member 10 is sandwiched between the drain electrode 51 and the source electrode 52 in the first direction Z.

The semiconductor member 10 is provided with a plurality of grooves for a gate electrode (first concave portions) 21 and a plurality of grooves for a source electrode (second concave portions) 22. The grooves for a gate electrode 21 and the grooves for a source electrode 22 are recessed downward from an upper surface of the semiconductor member 10. The grooves for a gate electrode 21 and the grooves for a source electrode 22 extend in the third direction Y and are alternately arranged in the second direction X. Accordingly, the grooves for a gate electrode 21 are provided on both sides of the grooves for a source electrode 22 in the second direction X.

Inner side surfaces of the grooves for a gate electrode 21 are provided with bottom faces 21a directed upward, and pairs of sidewalls 21b facing each other in the second direction X. Similarly, inner side surfaces of the grooves for a source electrode 22 are provided with bottom faces 22a directed upward, and pairs of sidewalls 22b facing each other in the second direction X. The grooves for a gate electrode 21 are formed deeper than the grooves for a source electrode 22.

The semiconductor member 10 includes a first semiconductor region 11, a second semiconductor region 12, and a third semiconductor region 15. The first semiconductor region 11, the second semiconductor region 12, and the third semiconductor region 15 are formed in a layered shape in the first direction Z. These semiconductor regions are disposed from top to bottom in the order of the first semiconductor region 11, the second semiconductor region 12, and the third semiconductor region 15. The first semiconductor region 11, the second semiconductor region 12, and the third semiconductor region 15 are all of the first conductivity type. The first semiconductor region 11, the second semiconductor region 12, and the third semiconductor region 15 are differentiated by their carrier concentrations. The first conductivity type is either n type or p type. In the embodiment, the first conductivity type is an n type. However, the first conductivity type may be a p type.

The first semiconductor region 11 is, for example, an n⁺ region. A carrier concentration of the first semiconductor region 11 is preferably equal to or greater than 1.0×10¹⁹ cm⁻³. The first semiconductor region 11 is located on an upper end portion of the semiconductor member 10. The first semiconductor region 11 is in contact with the source electrode 52. The first semiconductor region 11 forms an ohmic junction with the source electrode 52. Here, a portion of the first semiconductor region 11 that is in contact with the source electrode 52 and has formed an ohmic junction with the source electrode 52 is referred to as an ohmic junction portion 31. That is, the first semiconductor region 11 has the ohmic junction portion 31.

The second semiconductor region 12 is, for example, an n region. A carrier concentration of the second semiconductor region 12 is preferably 1.0×10¹⁴ cm⁻³ or more and 1.0×10¹⁸ cm⁻³ or less. A carrier concentration of the first conductivity type in the second semiconductor region 12 is lower than a carrier concentration of the first conductivity type in the first semiconductor region 11. The second semiconductor region 12 is located below the first semiconductor region 11.

The second semiconductor region 12 has a first partial region 12a, a second partial region (channel region) 12b, and a third partial region 12c. These partial regions are disposed from above to below in the order of the first partial region 12a, the second partial region 12b, and the third partial region 12c in the second semiconductor region 12.

The first partial region 12a is located between the groove for a gate electrode 21 and the groove for a source electrode 22. The first partial region 12a is located between the gate electrode 53 and the source electrode 52 in the second direction X. An upper end portion of the first partial region 12a is in contact with the first semiconductor region 11. In addition, the first partial region 12a is in contact with the source electrode 52. The first partial region 12a forms a Schottky junction with the source electrode 52. Here, a portion of the second semiconductor region 12 that is in contact with the source electrode 52 and forms a Schottky junction with the source electrode 52 is referred to as a Schottky junction portion 32. That is, the second semiconductor region 12 has the Schottky junction portion 32. In addition, the Schottky junction portion 32 is located between the groove for a gate electrode 21 and the groove for a source electrode 22.

The second partial region 12b is located below the first partial region 12a and between the groove for a gate electrode 21 and the groove for a source electrode 22. The second insulating layer 45 is disposed between the second partial region 12b and the source electrode 52. Accordingly, the second partial region 12b is not in direct contact with the source electrode 52. The second partial region 12b is located between the gate electrode 53 and the source electrode 52 in the second direction X.

The third partial region 12c is located below the second partial region 12b. The third partial region 12c is located below the bottom faces 22a of the grooves for a source electrode 22. The third partial region 12c has a portion located below the bottom faces 22a of the grooves for a source electrode 22. The third partial region 12c has an upper portion located above the bottom faces 21a of the grooves for a gate electrode 21, and a lower portion located below the bottom faces 21a of the grooves for a gate electrode 21. The third partial region 12c connects the second partial region 12b and the third semiconductor region 15.

The third semiconductor region 15 is, for example, an n⁺ region. A carrier concentration of the first conductivity type in the third semiconductor region 15 is, for example, 1.0×10¹⁷ cm⁻³ or more and 3.0×10²⁰ cm⁻³ or less. A carrier concentration of the first conductivity type in the third semiconductor region 15 may be higher than a carrier concentration of the first conductivity type in the second semiconductor region 12. In addition, the third semiconductor region 15 may have a carrier concentration higher than, lower than, or approximately the same as that of the first conductivity type in the first semiconductor region 11.

The third semiconductor region 15 of the embodiment is provided between the drain electrode 51 and the second semiconductor region 12 in the first direction Z. The third semiconductor region 15 is located below the grooves for a source electrode 22 and the grooves for a gate electrode 21. The third semiconductor region 15 is in contact with the drain electrode 51. The third semiconductor region 15 is electrically connected to the drain electrode 51. According to the embodiment, by providing the third semiconductor region 15 having a high carrier concentration in the semiconductor member 10, the resistance of the electrical connection of the drain electrode 51 can be reduced. Accordingly, for example, it is possible to reduce on-resistance of the semiconductor device 1.

When the semiconductor member 10 contains silicon, examples of impurities of the first conductivity type include pentavalent elements such as phosphorous, arsenic, or the like. That is, the impurities of the first conductivity type are n type impurities. In the embodiment, the semiconductor member 10 does not have a p-type semiconductor. For this reason, it is possible to simplify the manufacturing process of the semiconductor device 1.

Each of the drain electrode 51, the source electrode 52, the gate electrode 53, and the field plate 61 extends in the third direction Y. The gate electrode 53 and a part (a contact portion 52b described below) of the source electrode 52 are arranged in the second direction X. The gate electrode 53 and the field plate 61 are arranged in the first direction Z.

The drain electrode 51 is provided on a lower surface of the semiconductor member 10. The drain electrode 51 contains at least one selected from the group consisting of, for example, Al, Cu, Mo, W, Ta, Co, Ru, Ti, Ni, Au, and Pt.

The source electrode 52 is located above the semiconductor member 10. The source electrode 52 has an interconnection layer 52a, and the contact portion 52b. The interconnection layer 52a is located above an upper surface of the semiconductor member 10. The contact portion 52b is disposed in the groove for a source electrode 22. That is, at least a part of the source electrode 52 is disposed in the groove for a source electrode 22.

Electron affinity of the second semiconductor region 12 is lower than a work function of the source electrode 52. For this reason, the source electrode 52 forms a Schottky junction with the second semiconductor region 12. In addition, electron affinity of the first semiconductor region 11 is lower than a work function of the source electrode 52, like the second semiconductor region 12. However, the first semiconductor region 11 has a depletion layer width narrowed due to high impurity concentration, and forms an ohmic junction with the source electrode 52 due to a tunnel effect. That is, the source electrode 52 forms an ohmic junction with the first semiconductor region 11 and a Schottky junction with the second semiconductor region 12.

For example, when the semiconductor member 10 contains silicon, the source electrode 52 contains at least one selected from the group consisting of, for example, Ti, TiN, W, Mo, MoN, Ta, Zr, Al, Sn, V, VN, Re, Os, Ir, Pt, Pd, Rh, Ru, Nb, Sr, and Hf.

Further, in the embodiment, the case in which the interconnection layer 52a and the contact portion 52b of the source electrode 52 are formed of the same material has been described. However, the interconnection layer 52a and the contact portion 52b may be formed of different materials. In this case, the work function of the contact portion 52b need to have the aforementioned relationship with each region of the semiconductor member 10.

The gate electrode 53 is disposed in the groove for a gate electrode 21. The gate electrode 53 contains, for example, polysilicon. The gate electrode 53 is insulated from the semiconductor member 10. The gate electrode 53 and the contact portion 52b overlap each other in the second direction X. An upper end of the gate electrode 53 is located below an upper end of the contact portion 52b. A lower end of the gate electrode 53 is located below a lower end of the contact portion 52b.

The field plate 61 is disposed in the groove for a gate electrode 21. The field plate 61 is located below the gate electrode 53. The field plate 61 is insulated from the gate electrode 53 and the semiconductor member 10. In addition, the field plate 61 is electrically connected to the source electrode 52 via, for example, an interconnection 52L. Accordingly, the field plate 61 has the same potential as the source electrode 52.

The first insulating layer 42 is disposed in the groove for a gate electrode 21. The first insulating layer 42 surrounds each of the gate electrode 53 and the field plate 61. The first insulating layer 42 insulates the semiconductor member 10, the gate electrode 53 and the field plate 61 from each other. In addition, the first insulating layer 42 insulates the source electrode 52 from the gate electrode 53. The first insulating layer 42 contains at least one selected from the group consisting of, for example, silicon oxide, silicon nitride, and silicon oxynitride.

The second insulating layer 45 is formed on an inner side surface of the groove for a source electrode 22. The second insulating layer 45 contains at least one selected from the group consisting of, for example, silicon oxide, silicon nitride, and silicon oxynitride.

The second insulating layer 45 has a bottom face insulating portion 45a and a sidewall insulating portion 45b. The bottom face insulating portion 45a covers the bottom face 22a of the groove for a source electrode 22. The sidewall insulating portion 45b extends upward from the bottom face insulating portion 45a, and covers a lower region in the sidewall 22b of the groove for a source electrode 22. That is, the sidewall insulating portion 45b covers a part of the sidewall 22b.

A position of the upper end portion of the sidewall insulating portion 45b in the first direction Z coincides with a position of a boundary portion between the first partial region 12a and the second partial region 12b in the first direction Z. In other words, the first partial region 12a and the second partial region 12b are divided at the position of the upper end portion of the sidewall insulating portion 45b. Accordingly, the upper end portion of the sidewall insulating portion 45b is located below the ohmic junction portion 31 and the Schottky junction portion 32. And the upper end portion of the sidewall insulating portion 45b coincides with the upper end portion of the second partial region 12b in the first direction Z. The contact portion 52b disposed in the groove for a source electrode 22 is in direct contact with the first semiconductor region 11 and the first partial region 12a, and faces the second partial region 12b via the second insulating layer 45.

The second insulating layer 45 of the embodiment has a first layer 45c and a second layer 45d. The first layer 45c is located between the semiconductor member 10 and the contact portion 52b and on the side of the semiconductor member 10. Meanwhile, the second layer 45d is located between the semiconductor member 10 and the contact portion 52b and on the side of the contact portion 52b. That is, the second layer 45d is laminated on the first layer 45c. The first layer 45c is disposed between the second layer 45d and the second partial region 12b of the second semiconductor region 12.

In the embodiment, the first layer 45c is, for example, silicon oxide (SiO₂), and the second layer 45d is, for example, aluminum oxide (Al₂O₃). In addition, the first layer 45c may be lanthanum oxide (III) (La₂O₃), and the second layer 45d may be silicon oxide (SiO₂). Further, the first layer 45c may be lanthanum oxide (III) (La₂O₃), and the second layer 45d may be aluminum oxide (Al₂O₃).

A dipole effect can be expected in the second insulating layer 45 of the embodiment. In the second insulating layer 45, polarization occurs in each of the first layer 45c and the second layer 45d. Accordingly, an electric field is generated within the second insulating layer 45, and depletion in the second partial region 12b is promoted.

Next, an operating principle of the semiconductor device 1 of the embodiment will be described.

In the embodiment, the source electrode 52 and the first semiconductor region 11 form an ohmic junction. Accordingly, the source electrode 52 and the first semiconductor region 11 are electrically connected to each other. In addition, since the work function of the metal material that forms the contact portion 52b of the source electrode 52 is higher than the electron affinity of the second partial region 12b, a depletion layer is formed on the second partial region 12b. Further, the first layer 45c and the second layer 45d of the second insulating layer 45 promote depletion of the second partial region 12b by a dipole effect of polarizing each other. Accordingly, when the voltage is not applied to the gate electrode 53, the depletion layer creates an OFF state in which no current flows through the second partial region 12b. By controlling the potential of the gate electrode 53, an electron accumulation layer is formed in the second partial region 12b, resulting in an ON state in which a drain current flows in the second partial region 12b. Accordingly, in the semiconductor device 1, the current between the drain electrode 51 and the source electrode 52 is controlled by the potential of the gate electrode 53. Further, here, the potential of the gate electrode 53 is the potential based on the potential of the source electrode 52.

In the embodiment, even though the work function of the metal material that forms the contact portion 52b is low, when the dipole effect of the second insulating layer 45 is sufficiently high, the depletion layer can be sufficiently formed on the second partial region 12b. In addition, when the work function of the metal material that forms the contact portion 52b is sufficiently high, even though the second insulating layer 45 does not exhibit a dipole effect, the depletion layer can be sufficiently formed in the second partial region 12b.

In the embodiment, when the work function of the metal material that forms the contact portion 52b is sufficiently high, the depletion layer is also formed on the first partial region 12a that forms a Schottky junction with the contact portion 52b. In the embodiment, since the first partial region 12a is located between the gate electrode 53 and the contact portion 52b, in the ON state, the electron accumulation layer is also formed in the first partial region 12a, and a drain current flows therethrough.

In the embodiment, the contact portion 52b and the first partial region 12a of the source electrode 52 form a Schottky junction. For this reason, the contact portion 52b and the first partial region 12a function as a Schottky barrier diode S, and it is possible to flow the current from the contact portion 52b to the first partial region 12a. Here, when a strong electric field is formed in the first partial region 12a that forms a Schottky junction with the source electrode 52, leakage current of the Schottky barrier diode S may increase. Here, a strong electric field is likely formed in the semiconductor member 10 in the vicinity of the bottom face 22a of the groove for a source electrode 22. According to the embodiment, the bottom faces 22a of the grooves for a source electrode 22 and portions of the sidewalls 22b connected to the bottom faces 22a are covered with the second insulating layer 45, and the Schottky junction portion 32 is positioned above the bottom faces 22a. For this reason, a strong electric field is less likely to be generated in the Schottky junction portion 32, which suppresses the leakage current of the Schottky barrier diode S. In addition, according to the embodiment, the bottom faces 22a and portions of the sidewalls 22b connected to the bottom faces 22a are covered with the second insulating layer 45, thereby limiting the area of the Schottky junction portion 32. Accordingly, it is possible to suppress the leakage current of the Schottky barrier diode.

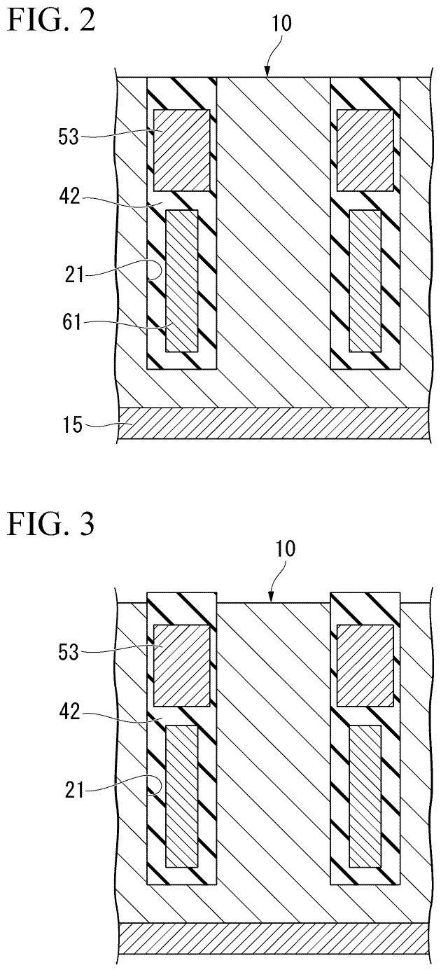

Next, a method of manufacturing the semiconductor device 1 of the embodiment will be described with reference to FIG. 2 to FIG. 11. In the method of manufacturing the semiconductor device 1 of the embodiment, first, the semiconductor member 10 containing n type impurities as a whole is prepared. Next, n type impurities are diffused into a lower end portion of the semiconductor member 10 to form the third semiconductor region 15 having a high concentration of n type impurities. Further, the third semiconductor region 15 may be prepared, and the semiconductor member 10 may be formed by epitaxial growth or the like.

Next, as shown in FIG. 2, the grooves for a gate electrode 21 are formed on the semiconductor member 10, and then the field plate 61 and the gate electrode 53 embedded in the first insulating layer 42 are formed inside the grooves for a gate electrode 21.

Next, as shown in FIG. 3, the upper surface of the semiconductor member 10 is etched. Accordingly, the first insulating layer 42 protrudes from the upper surface of the semiconductor member 10.

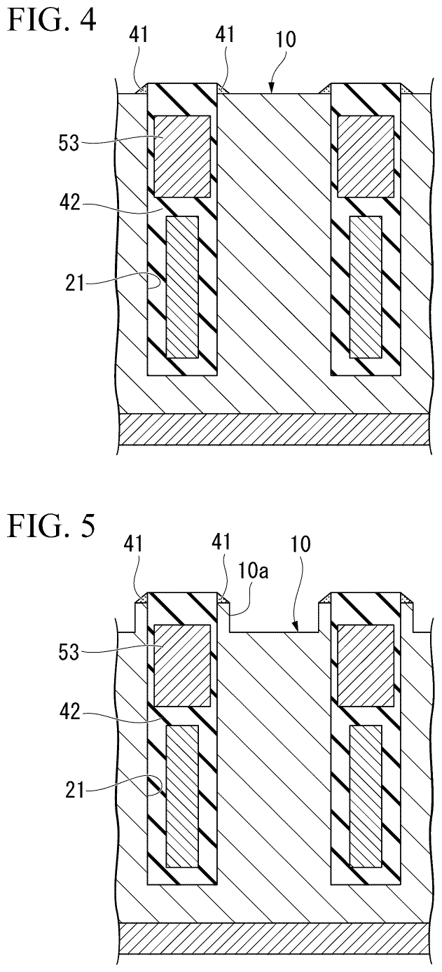

Next, as shown in FIG. 4, sidewalls 41 are formed on both left and right sides of the upper end portion of the first insulating layer 42 protruding from the upper surface of the semiconductor member 10. The sidewalls 41 are formed, for example, by forming an insulating film on the surfaces of the first insulating layer 42 and the semiconductor member 10 using a film formation method such as CVD or the like, and then etching the insulating film using anisotropic etching. After the etching, the insulating film remaining on both left and right sides of the upper end portion of the first insulating layer 42 are the sidewalls 41.

Next, as shown in FIG. 5, a preliminary concave portion 10a is formed by performing anisotropic etching of the semiconductor member 10. In addition, here, the sidewalls 41 function as a mask, and the portion of the semiconductor member 10 directly below the sidewalls 41 is not etched. For this reason, the preliminary concave portion 10a is formed in a region that is separated from the grooves for a gate electrode 21 by the thickness of the sidewalls 41 in the leftward/rightward direction.

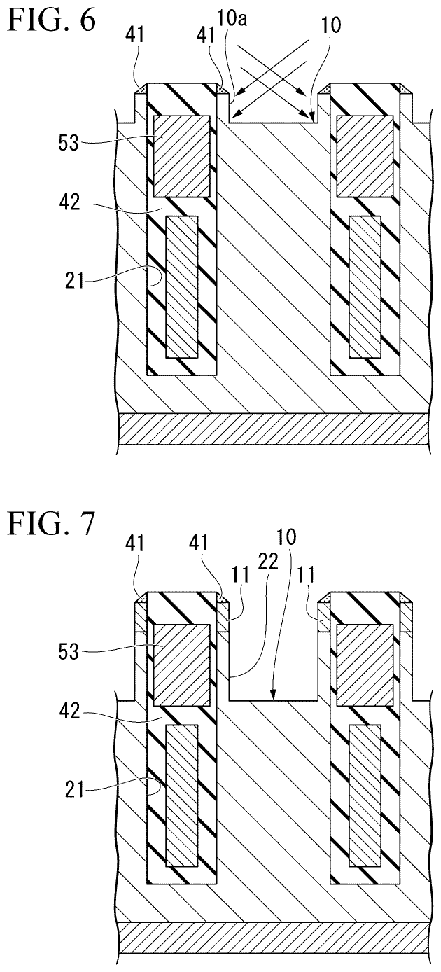

Next, as shown in FIG. 6, n type impurities are ion-injected to the upper surface of the semiconductor member 10. Accordingly, as shown in FIG. 7, the first semiconductor region 11 is formed in an upper portion of the semiconductor member 10, in which n-type impurities are diffused at a high concentration.

Next, as shown in FIG. 7, anisotropic etching of the semiconductor member 10 is performed, and the grooves for a source electrode 22 are formed in the semiconductor member 10. Here, since the sidewalls 41 function as a mask, the grooves for a source electrode 22 are formed in a region that is separated from the grooves for a gate electrode 21 by the thickness of the sidewalls 41 in the leftward/rightward direction. According to the embodiment, a distance between the groove for a source electrode 22 and the groove for a gate electrode 21 can be accurately adjusted by a dimension of the sidewall 41. For this reason, a dimension in the second direction X of the second partial region 12b shown in FIG. 1 can be accurately controlled, and it is possible to manufacture the semiconductor device 1 in which the variation in the gate threshold voltage is suppressed.

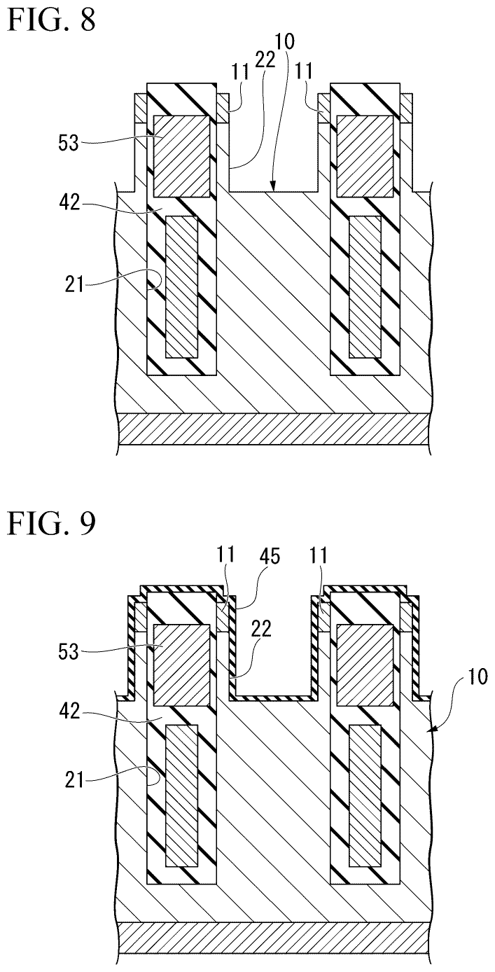

Next, as shown in FIG. 8, the sidewalls 41 are removed. Next, as shown in FIG. 9, the second insulating layer 45 is formed on the surfaces of the semiconductor member 10 and the first insulating layer 42. In the process of forming the second insulating layer 45, the second layer 45d is formed after the first layer 45c shown in FIG. 1 is formed.

Next, as shown in FIG. 10, a lower region of the contact portion 52b is formed in the groove for a source electrode 22. In the process of forming the lower region of the contact portion 52b, for example, first, a film of a material that forms the contact portion 52b is formed above the semiconductor member 10 to fill the grooves for a source electrode 22. Next, a portion of the film that covers an upper region of the sidewall 22b of the groove for a source electrode 22 is removed by, for example, reactive ion etching (RIE) or the like. Accordingly, only the lower region of the contact portion 52b remains.

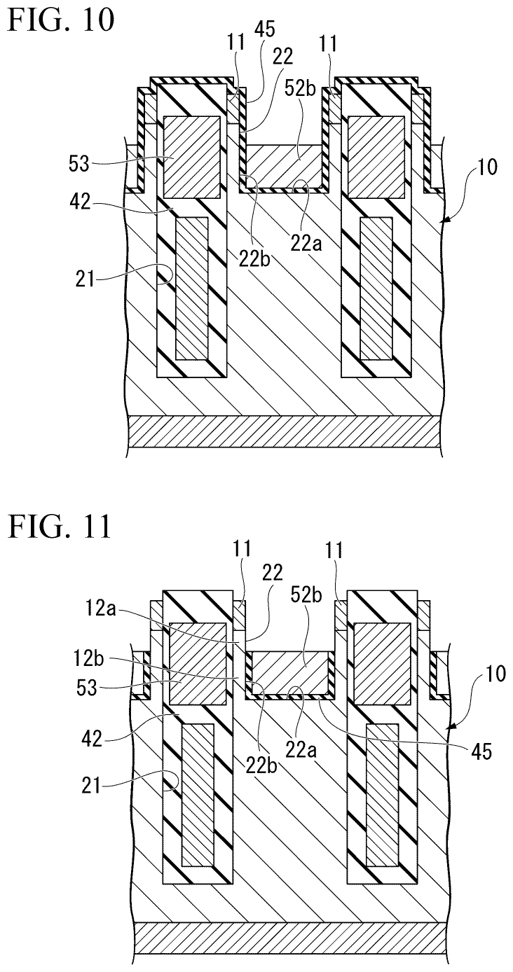

Next, as shown in FIG. 11, the second insulating layer 45 is etched until the first partial region 12a is exposed. Further, as shown in FIG. 1, the source electrode 52 is formed to cover the first partial region 12a, and the drain electrode 51 is formed below the semiconductor member 10.

In this way, the semiconductor device 1 is obtained. Further, the method of manufacturing the semiconductor device 1 of the embodiment is an example, and the semiconductor device 1 may be manufactured by another procedure.

Next, effects of the embodiment will be described.

The semiconductor device 1 of the embodiment has the semiconductor member 10, the source electrode 52, the drain electrode 51, the gate electrode 53, and the second insulating layer 45. The semiconductor member 10 are provided with the grooves for a gate electrode 21 and the grooves for a source electrode 22 arranged in the second direction X. The grooves for a gate electrode 21 and the grooves for a source electrode 22 are recessed downward from the upper surface. The source electrode 52 is located above the semiconductor member 10. At least a part of the source electrode 52 is located in the groove for a source electrode 22. The drain electrode 51 is located below the semiconductor member 10. At least a part of the gate electrode 53 is located in the groove for a gate electrode 21. The second insulating layer 45 is located between the inner side surface of the groove for a source electrode 22 and the source electrode. The semiconductor member 10 includes the first semiconductor region 11 of the first conductivity type, and the second semiconductor region 12 of the first conductivity type. The second semiconductor region 12 is located below the first semiconductor region 11. The second semiconductor region 12 has a carrier concentration lower than that of the first semiconductor region 11. The first semiconductor region 11 has the ohmic junction portion 31. The ohmic junction portion 31 forms an ohmic junction with the source electrode 52. The second semiconductor region 12 has the Schottky junction portion 32, and the second partial region 12b. The Schottky junction portion 32 forms a Schottky junction with the source electrode 52. The second partial region 12b is located between the gate electrode 53 and the source electrode 52 in the second direction X. The second insulating layer 45 has the bottom face insulating portion 45a, and the sidewall insulating portion 45b. The bottom face insulating portion 45a covers the bottom face 22a of the groove for a source electrode 22. The sidewall insulating portion 45b extends upward from the bottom face insulating portion 45a and covers a part of the sidewall 22b of the groove for a source electrode 22. The upper end portion of the sidewall insulating portion 45b is located below the ohmic junction portion 31 and the Schottky junction portion 32 and coincides with the upper end portion of the second partial region 12b in the first direction Z.

According to this configuration, the source electrode 52 can form a Schottky junction with the second semiconductor region 12 to configure the Schottky barrier diode S. The Schottky barrier diode S is likely to increase leakage current when the electric field strength at the Schottky junction portion 32 is high. In addition, the electric field strength of the semiconductor member 10 tends to be higher below the bottom faces 22a of the grooves for a source electrode 22. According to this configuration, since the Schottky junction portion 32 is located above the bottom faces 22a of the grooves for a source electrode 22, the electric field strength of the semiconductor member 10 at the Schottky junction portion 32 can be reduced, and the leakage current of the Schottky barrier diode S can be suppressed.

In the semiconductor device 1 of the embodiment, the lower end portion of the gate electrode 53 is located below the lower end portion of the source electrode 52. According to this configuration, it is possible to secure a sufficiently wide region (channel region) in which depletion can be controlled by the voltage of the gate electrode.

In the semiconductor device 1 of the embodiment, the ohmic junction portion 31, the Schottky junction portion 32, and the second partial region 12b are disposed side by side in the first direction Z between the grooves for a gate electrode 21 and the grooves for a source electrode 22. According to this configuration, it is possible to configure the semiconductor device 1 in which the ohmic junction portion 31, the Schottky junction portion 32, and the second partial region 12b are densely disposed.

In the semiconductor device 1 of the embodiment, the Schottky junction portion 32 is disposed between the gate electrode 53 and the source electrode 52 in the second direction X. According to this configuration, even if the depletion layer is formed in the first partial region 12a due to the effect of the Schottky junction, the electron accumulation layer can be formed in the first partial region 12a by controlling the potential of the gate electrode 53, making it possible to flow the drain current even in the first partial region 12a.

In the semiconductor device 1 of the embodiment, the second insulating layer 45 contains a plurality of polarizing layers (the first layer 45c and the second layer 45d). The second partial region 12b is depleted by the dipole effect of the second insulating layer 45. According to this configuration, even if the work function of the metal material constituting the source electrode 52 is not sufficiently high, the depletion layer can be formed in the second partial region 12b by the dipole effect of the second insulating layer 45. Accordingly, since there is no need to use an expensive metal material for the source electrode 52, the semiconductor device 1 can be manufactured at low cost.

In the semiconductor device 1 of the embodiment, the carrier concentration of the first semiconductor region 11 is preferably equal to or greater than 1.0×10¹⁹ cm⁻³, and the carrier concentration of the second semiconductor region 12 is preferably equal to or smaller than 1.0×10¹⁸ cm⁻³. As described above, the first semiconductor region 11 forms an ohmic junction with the source electrode 52, and the second semiconductor region 12 forms a Schottky junction with the source electrode 52. Whether the junction state between the semiconductor member 10 and the metal material is an ohmic junction or a Schottky junction depends on the carrier concentration of the semiconductor member 10 and the work function of the metal material. Generally, the source electrode 52 is made of Ti, TiN, W, or the like, taking into consideration the material characteristics and cost. When these metal materials are used, by setting the carrier concentration of the first semiconductor region 11 to 1.0×10¹⁹ cm⁻³ or more, the first semiconductor region 11 can be made to form an ohmic junction with the source electrode 52, and by setting the carrier concentration of the second semiconductor region 12 to 1.0×10¹⁸ cm⁻³ or less, the second semiconductor region 12 can be made to form a Schottky junction with the source electrode 52.

In the semiconductor device 1 of the embodiment, the work function of the metal material that forms the source electrode 52 is preferably 4.4 eV or more. The carrier concentration of the second semiconductor region 12 is generally 1.0×10¹⁴ cm⁻³ or more to sufficiently suppress the on-resistance. By setting the work function of the metal material that forms the source electrode 52 to 4.4 eV or more, when the carrier concentration of the second semiconductor region 12 is 1.0×10¹⁴ cm⁻³ or more, the second semiconductor region 12 can form a Schottky junction with the source electrode 52. In addition, if the metal material that forms the source electrode 52 has a high work function, the source electrode 52 can promote depletion of the second partial region 12b through the second insulating layer 45. Accordingly, it is also possible to use an insulating layer that does not have a dipole effect or an insulating layer that has a low dipole effect as the second insulating layer 45. Further, when the interconnection layer 52a and the contact portion 52b of the source electrode 52 are made of different metal materials, the work function of the metal material of the contact portion 52b may be within the above-mentioned range.

The semiconductor device 1 of the embodiment has the field plate 61. The field plate 61 is located in the grooves for a gate electrode 21 and below the gate electrode 53. The field plate 61 is insulated from the gate electrode 53 and conductive to the source electrode 52. According to this configuration, by providing the field plate 61 in the grooves for a gate electrode 21, the electric field strength of the drift layer in the second semiconductor region 12 can be reduced. Accordingly, it is possible to improve withstand voltage characteristics between the drain electrode 51 and the source electrode 52 of the semiconductor member 10. In addition, as the pressure resistance improves, the impurity concentration of the second semiconductor region 12 can be set high, and the on-resistance of the semiconductor device 1 can be reduced. In addition, by providing the field plate 61, the electric field strength of the first partial region 12a can also be reduced, and the leakage current of the Schottky barrier diode S can be suppressed. Further, in the embodiment, although the semiconductor device 1 has been described as having the field plate 61, the semiconductor device 1 may not have the field plate 61.

According to at least one of the embodiments described above, the leakage current of the Schottky barrier diode S can be suppressed by having the Schottky junction portion 32 located above the upper end portion of the bottom insulating portion.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a semiconductor member provided with a first concave portion and a second concave portion recessed from a surface on a first side in a first direction to a second side opposite to the first side and arranged in a second direction crossing the first direction;
a source electrode, located on the first side of the semiconductor member, at least a part of which is located in the second concave portion;
a drain electrode located on the second side of the semiconductor member;
a gate electrode, at least a part of which is located in the first concave portion; and
an insulating layer located between an inner side surface of the second concave portion and the source electrode,
wherein the semiconductor member includes a first semiconductor region of a first conductivity type; and
a second semiconductor region of a first conductivity type located on the second side of the first semiconductor region and having a carrier concentration lower than that of the first semiconductor region,
the first semiconductor region has an ohmic junction portion that forms an ohmic junction with the source electrode,
the second semiconductor region has:
a Schottky junction portion that forms a Schottky junction with the source electrode; and
a channel region located between the gate electrode and the source electrode in the second direction,
the insulating layer has:
a bottom face insulating portion configured to cover a bottom face of the second concave portion; and
a sidewall insulating portion extending from the bottom face insulating portion to the first side and configured to cover a part of a sidewall of the second concave portion, and
an end portion of the sidewall insulating portion on the first side is located on the second side of the ohmic junction portion and the Schottky junction portion and coincides with an end portion of the first side of the channel region in the first direction.

2. The semiconductor device according to claim 1, wherein an end portion of the gate electrode on the second side is located on the second side of the end portion of the source electrode on the second side.

3. The semiconductor device according to claim 1, wherein the ohmic junction portion, the Schottky junction portion, and the channel region are disposed side by side in the first direction between the first concave portion and the second concave portion.

4. The semiconductor device according to claim 1, wherein the insulating layer contains a plurality of polarizing layers.

5. The semiconductor device according to claim 4, wherein the insulating layer includes a first layer and a second layer located on the side of the source electrode from the first layer as the plurality of layers,
the first layer is silicon oxide, and
the second layer is aluminum oxide.

6. The semiconductor device according to claim 1, wherein a carrier concentration of the first semiconductor region is 1.0×10¹⁹ cm⁻³ or more, and
a carrier concentration of the second semiconductor region is 1.0×10¹⁸ cm⁻³ or less.

7. The semiconductor device according to claim 6, wherein a work function of a metal material that forms the source electrode is 4.4 eV or more.

8. The semiconductor device according to claim 1, comprising a conductive member located in the first concave portion and on the second side of the gate electrode,
wherein the conductive member is insulated from the gate electrode and conductive to the source electrode.
